(19) United States
(12) Patent Application Publication
(10) Pub. No.: US 2026/0160788 A1
(43) Pub. Date: Jun. 11, 2026

(54) ELECTRIC CURRENT MEASUREMENT CIRCUIT, STAGE APPARATUS, AND CONTROL METHOD OF ACTUATOR

(71) Applicant: SUMITOMO HEAVY INDUSTRIES, LTD., Tokyo (JP)

(72) Inventor: Ken TAKAYAMA, Yokosuka-shi (JP)

(21) Appl. No.: 19/413,086

(22) Filed: Dec. 9, 2025

(30) Foreign Application Priority Data
Dec. 11, 2024 (JP) 2024-216268

(51) Int. Cl. G01R 19/25; G01R 15/20; G01R 19/18; H02P 27/06

(52) U.S. Cl. CPC G01R 19/25; G01R 15/202; G01R 19/18; H02P 27/06; H02P 2205/01

(57) ABSTRACT

A current measurement circuit includes a plurality of current sensors that are inserted in a current path, that each have a different relationship between a current flowing through the current path and a sensor output, and that are connected in series with each other, and a selection circuit that selects, based on a plurality of sensor outputs from the plurality of current sensors, one sensor output from among the plurality of sensor outputs and that outputs the selected sensor output as a current measurement value.

### CROSS-REFERENCE TO RELATED APPLICATIONS

This application claims priority to Japanese Patent Application No. 2024-216268, filed on Dec. 11, 2024, which is incorporated by reference herein in its entirety.

### BACKGROUND

### Technical Field

Certain embodiments of the present invention relate to a current measurement circuit, a stage apparatus, and a control method of an actuator.

Description of Related Art

A circuit that switches between two current measurement units in accordance with magnitude of a current flowing through a current path that is a measurement target, to measure the current is known (related art). The current measurement unit that measures a small current measures a current flowing through a transistor for current measurement connected in parallel to a transistor that causes the current to flow through the current path. The current measurement unit that measures a large current is connected in series with the transistor that causes the current to flow through the current path, and directly measures the current flowing through the current path. When a small current is measured, a switch connected in parallel to the current measurement unit for a large current is turned on, so that a loss caused by the current measurement unit is reduced.

### SUMMARY

According to an embodiment of the present invention, there is provided a current measurement circuit including: a plurality of current sensors that are inserted in a current path, that each have a different relationship between a current flowing through the current path and a sensor output, and that are connected in series with each other; and a selection circuit that selects, based on a plurality of sensor outputs from the plurality of current sensors, one sensor output from among the plurality of sensor outputs and that outputs the selected sensor output as a current measurement value.

According to another embodiment of the present invention, there is provided a stage apparatus including: the current measurement circuit described above; a movable stage; an actuator driven by the inverter to move the movable stage; and a driver that controls the inverter based on an output from the current measurement circuit.

According to still another embodiment of the present invention, there is provided a control method including: measuring a current flowing through a current path using a plurality of current sensors that are inserted in series in the current path and that each have a different relationship between the current flowing through the current path and a sensor output; and selecting, based on a plurality of sensor outputs of the plurality of current sensors, one sensor output from among the plurality of current sensors and controlling an actuator based on the selected sensor.

### BRIEF DESCRIPTION OF THE DRAWINGS

FIG. 1 is a block diagram of a current measurement circuit according to one embodiment.

FIG. 2 is a graph showing an example of a relationship between a current flowing through a current path and output voltages of current measurement elements, and a relationship between a current sensor selected by a selection circuit and the current.

FIG. 3 is a graph showing an example of a relationship between the current and a digital-converted output voltage.

FIG. 4 is a block diagram of a stage apparatus according to another embodiment.

FIG. 5 is a flowchart showing a procedure of controlling a motor.

### DETAILED DESCRIPTION

In the circuit disclosed in the related art, the switch is turned on and off when a large current is measured and when a small current is measured, and thus noise generated during switching is superimposed on the current. It is desirable to provide a current measurement circuit that can suppress generation of noise in a current path that is a measurement target. Further, it is desirable to provide a control method of controlling an actuator using the current measurement circuit.

Since a plurality of current sensors are connected in series with each other and are inserted in a current path, a current flowing through the current path always flows through the plurality of current sensors, and sensor outputs are always obtained from the plurality of current sensors. Since a selection circuit selects one of a plurality of sensor outputs, there is no influence on the current path during selection. Therefore, it is possible to suppress the generation of noise in the current path that is the measurement target.

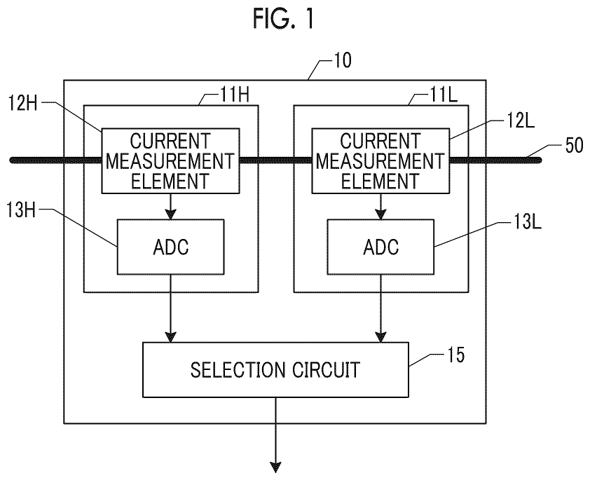

A current measurement circuit according to one embodiment will be described with reference to FIGS. 1 to 3.

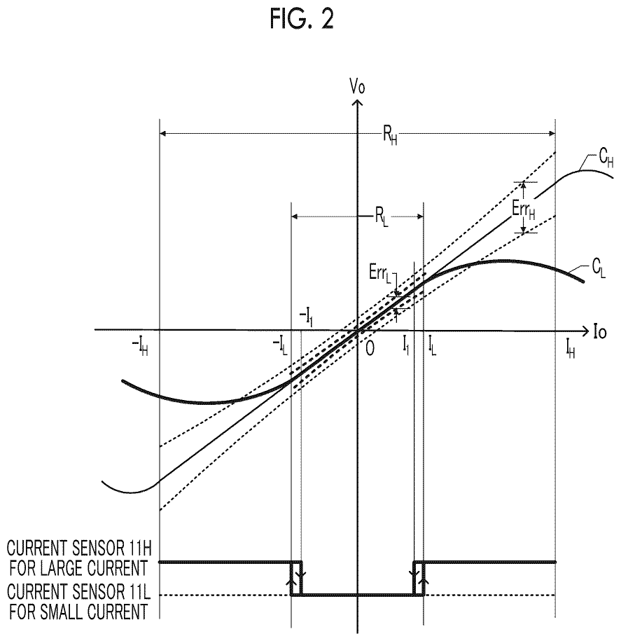

FIG. 1 is a block diagram of a current measurement circuit 10 according to the one embodiment. The current measurement circuit 10 includes two current sensors 11H and 11L and a selection circuit 15. The two current sensors 11H and 11L are connected in series with each other, and are inserted in a current path 50 that is a measurement target and through which a current flows. As will be described with reference to FIG. 2, a relationship between the current flowing through the current path 50 and a sensor output is different between the two current sensors 11H and 11L. The current sensor 11H is a sensor for a large current, and the current sensor 11L is a sensor for a small current.

The current sensor 11H for a large current includes a current measurement element 12H and an AD converter 13H, and the current sensor 11L for a small current includes a current measurement element 12L and an AD converter 13L. Each of the current measurement elements 12H and 12L outputs a voltage corresponding to the current flowing through the current path 50. For example, a Hall element can be used as the current measurement elements 12H and 12L.

The AD converters 13H and 13L convert the voltages (analog signals) output from the current measurement elements 12H and 12L into digital signals, respectively. The digital signal that is AD-converted will be referred to as a “sensor output”. A resolution and a full-scale voltage value are different between the two AD converters 13H and 13L.

The selection circuit 15 selects, based on the sensor outputs from the current sensors 11H and 11L, one sensor output from among the two sensor outputs, and outputs the selected sensor output as a current measurement value. The selection circuit 15 is configured by, for example, a field-programmable gate array (FPGA). When the selection circuit 15 is configured by the FPGA, processing can be performed at a higher speed than in a case where the selection circuit 15 is configured by a CPU and software.

Next, input and output characteristics of the two current measurement elements 12H and 12L (FIG. 1) will be described with reference to FIG. 2. FIG. 2 is a graph showing an example of a relationship between a current Io flowing through the current path 50 (FIG. 1) and output voltages Vo of the current measurement elements 12H and 12L, and a relationship between the current sensor selected by the selection circuit 15 (FIG. 1) and the current Io. A horizontal axis represents the current Io, a vertical axis of an upper graph represents the output voltages Vo of the current measurement elements 12H and 12L, and a vertical axis of a lower graph represents the current sensors 11H and 11L.

A thin solid line in the upper graph shows input and output characteristics C_{H} of the current measurement element 12H for a large current, and a thick solid line shows input and output characteristics C_{L} of the current measurement element 12L for a small current. The input and output characteristics C_{H} and C_{L} are symmetrical with respect to an origin O. A linear characteristic range R_{H} of the current measurement element 12H for a large current is wider than a linear characteristic range R_{L} of the current measurement element 12L for a small current. The maximum values of the linear characteristic ranges R_{H} and R_{L} are denoted as I_{H} and I_{L}, respectively.

Since the two current sensors 11H and 11L are connected in series with each other and are inserted in the current path 50, the same current flows through the two current measurement elements 12H and 12L. That is, the same current as the current flowing through the current measurement element 12H for a large current also flows through the current measurement element 12L for a small current. Therefore, as the current measurement element 12L for a small current, a current measurement element having a rated current value equal to or higher than the maximum value I_{H} of the current in the linear characteristic range R_{H} of the current measurement element 12H for a large current is used. However, when the current Io exceeds the maximum value I_{L} of the current in the linear characteristic range R_{L}, the output of the current measurement element 12L for a small current is saturated.

A measurement error Err_{H} of the current measurement element 12H for a large current is larger than a measurement error Err_{L} of the current measurement element 12L for a small current. In FIG. 2, examples of ranges of the measurement errors Err_{H} and Err_{L} are shown by a broken line. In FIG. 2, the range of the measurement errors Err_{H} and Err_{L} are shown on an exaggerated scale relative to the actual ranges.

The selection circuit 15 provisionally determines a current value of the current Io based on the sensor output of the current sensor 11H for a large current. The selection circuit 15 selects the sensor output of the current sensor 11L for a small current when the provisionally determined current value is within the linear characteristic range R_{L}. When the current Io increases and the provisionally determined current value exceeds the maximum value I_{L} of the linear characteristic range R_{L} of the current sensor 11L for a small current, the selection circuit 15 switches the current sensor to be selected, from the current sensor 11L for a small current to the current sensor 11H for a large current. When the current Io decreases and the provisionally determined current value is equal to or smaller than a switching threshold I₁, the selection circuit 15 switches the current sensor to be selected, from the current sensor 11L for a small current to the current sensor 11H for a large current. The switching threshold I₁ is set to be smaller than the maximum value I_{L} of the linear characteristic range R_{L}. In this way, the hysteresis characteristics are provided at the time of the current switching.

Since the current sensor 11L for a small current is selected when the current Io is a small current, the measurement error is smaller than the measurement error in a case where the current is measured using the current sensor 11H for a large current. In addition, since the current sensor 11H for a large current is selected when the current Io exceeds the linear characteristic range R_{L} of the current sensor 11L for a small current, the current Io can be measured while maintaining linearity.

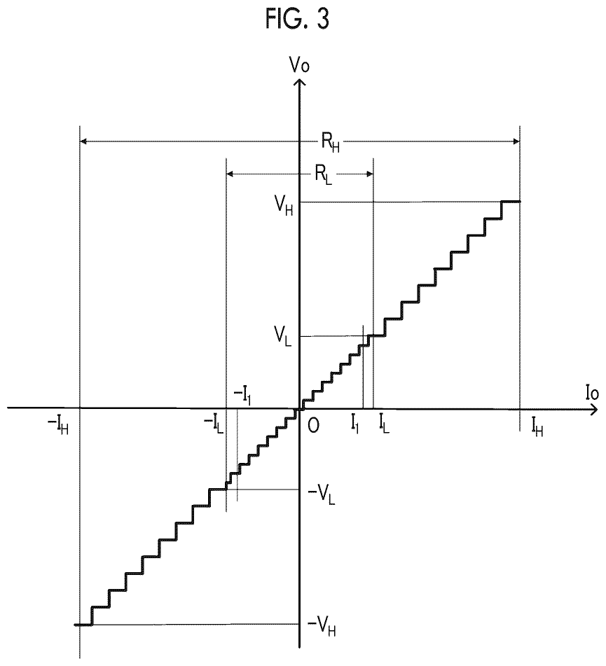

Next, a relationship between the output voltage Vo converted into the digital signal and the current Io will be described with reference to FIG. 3. FIG. 3 is a graph showing an example of the relationship between the current Io and the digital-converted output voltage Vo. A quantization error is generated when the AD converters 13H and 13L convert the voltages (analog signals) output from the current measurement elements 12H and 12L into the digital signals. Due to the quantization error, the output voltage Vo changes stepwise with respect to the current Io. In FIG. 3, the quantization error is shown on an exaggerated scale relative to the actual quantization error.

The full scale of the AD converter 13L of the current sensor 11L for a small current is set based on the output voltage V_{L} when the current corresponding to the maximum value I_{L} of the current in the linear characteristic range R_{L} flows. The full scale of the AD converter 13H of the current sensor 11H for a large current is set based on the output voltage V_{H} when the current corresponding to the maximum value I_{H} of the current in the linear characteristic range R_{H} flows. As the AD converter 13L of the current sensor 11L for a small current, an AD converter having a resolution higher than the resolution of the AD converter 13H of the current sensor 11H for a large current in a range in which the voltage is within the output voltage V_{L} is used. Therefore, the quantization error is smaller than the quantization error in a case where the current is measured using only the current sensor 11H for a large current.

Next, an excellent effect of the one embodiment will be described.

In the one embodiment, the current measurement range can be widened and the measurement error (measurement errors Err_{L} and Err_{H} in FIG. 2 and quantization errors shown in FIG. 3) in the small current region can be reduced by the current sensor 11H for a large current and the current sensor 11L for a small current. Further, the quantization error in the small current region can be reduced.

Since the two current sensors 11H and 11L inserted in series in the current path 50 are connected in series with each other, the current Io is always measured by the two current sensors 11H and 11L. When the current Io changes across the maximum value I_{L} of the current in the linear characteristic range R_{L} for a small current and the switching threshold I₁, and the sensor output to be selected switches between the two current sensors 11H and 11L, the current path 50 (FIG. 1) does not affect any switching. Therefore, it is possible to prevent noise from being generated at the time of switching.

In the one embodiment, the Hall element is used as the current measurement elements 12L and 12H. In the Hall element, a voltage generated by a Hall effect is measured and output by an isolation amplifier, and thus the current path (primary-side circuit) that is the measurement target and an output terminal (secondary-side circuit) that outputs a measurement result are isolated from each other. Therefore, high safety can be ensured. In addition, when a large current flows through the current path that is the measurement target, the Hall element for a small current is used in a non-linear region, but it is possible to select an element having specifications in which the current in the non-linear region falls within a rated range. Further, in the Hall element for current measurement, a constant magnetic field is applied to a current path formed of a semiconductor, and the magnetic field is not changed depending on the magnitude of the current. Therefore, the magnetic saturation caused by the characteristics of the magnetic material does not occur.

Next, a modification of the one embodiment will be described.

In the one embodiment, the two current sensors 11H and 11L connected in series with each other are inserted in the current path 50 (FIG. 1), but three or more current sensors connected in series with each other may be inserted in the current path 50. In addition, in the one embodiment, the Hall element is used as the current measurement elements 12H and 12L, but other current measurement elements that output a voltage corresponding to an amount of current may be used.

For example, a current transformer designed so that the magnetic saturation does not occur at the maximum current (current I_{H} in FIG. 2) may be used as the current measurement element 12L for a small current, and a shunt resistor may be used as the current measurement element 12H for a large current. By designing the current measurement element 12L for a small current so that the magnetic saturation does not occur at the maximum current (current I_{H} in FIG. 2), the current transitions within a range in which the magnetic saturation does not occur even in a case where the current transitions from a large current (current larger than the current I_{L} in FIG. 2) to a small current (current smaller than the current I_{L} in FIG. 2). Therefore, a decrease in the reading accuracy of the current value is suppressed as compared to a case where the magnetic saturation transitions from a state where the magnetic saturation occurs in the current measurement element 12L (low inductance state) to a state where the magnetic saturation does not occur. In addition, as the current measurement element 12L for a small current and the current measurement element 12H for a large current, two current transformers having different numbers of turns of the secondary-side windings may be used.

In the one embodiment, as shown in FIG. 2, in the linear characteristic range R_{L} of the current measurement element 12L for a small current, the relationship between the current Io and the output voltage Vo is the same between the current measurement element 12H for a large current and the current measurement element 12L for a small current. As another configuration, in the linear characteristic range R_{L} of the current measurement element 12L for a small current, the relationship between the current Io and the output voltage Vo may be different between the current measurement element 12H for a large current and the current measurement element 12L for a small current. For example, an element may be used in which, for the same current Io, the output voltage Vo of the current measurement element 12L for a small current is higher than the output voltage Vo of the current measurement element 12H for a large current.

As in the modification of the one embodiment described above, in a case where the current transformer is used as the current measurement elements 12L and 12H, it is necessary to prevent the magnetic saturation even when a large current flows. In order to prevent the magnetic saturation even when a large current flows, it is necessary to increase the dimensions of the magnetic material, so that the element may increase in size due to the rated maximum current. On the other hand, in a case where the Hall element is used, there is an advantage that the magnetic saturation does not occur as already described.

In addition, in a case where the shunt resistor is used for the current measurement elements 12L and 12H, the primary-side circuit and the secondary-side circuit are not insulated from each other, and thus it is preferable to insert an insulating IC in a subsequent stage in order to ensure sufficient safety. Further, a large current also flows through the shunt resistor for a small current, so that abnormal heat generation may occur, and the shunt resistor for a small current may be damaged. In a case where the Hall element is used, as already described, the primary-side circuit and the secondary-side circuit are insulated from each other, and thus sufficient safety is ensured. Further, as already described, it is possible to use, as the Hall element for a small current, an element having specifications not causing damage even when a large current flows.

As described above, from the viewpoints of the magnetic saturation, the damage to the element, and the like, it is more preferable to use the Hall element as the current measurement elements 12L and 12H than to use the current transformer or the shunt resistor.

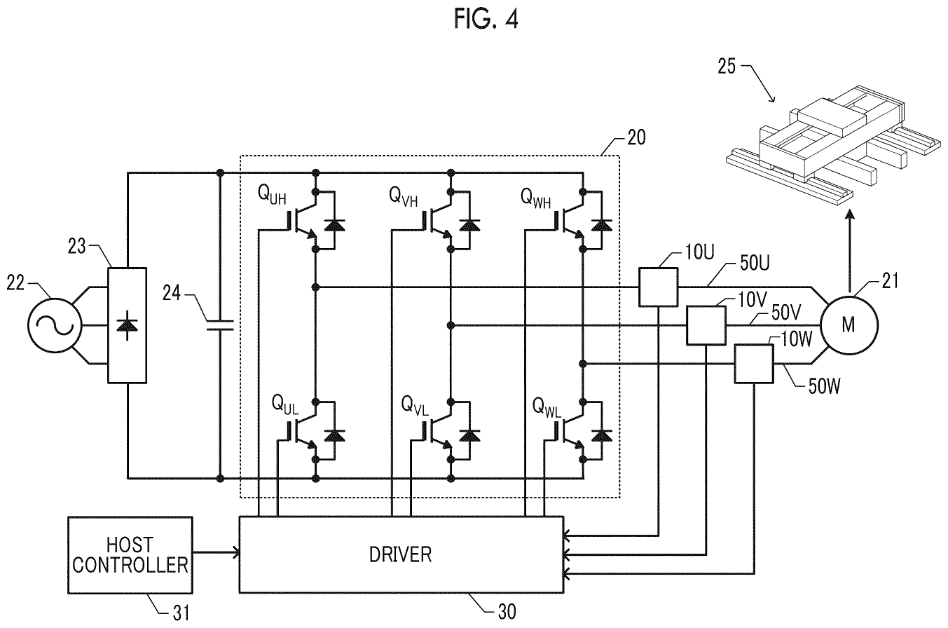

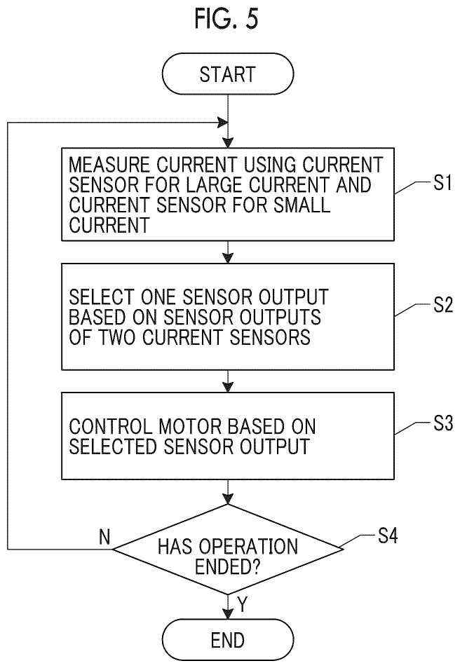

Next, a stage apparatus and a control method according to another embodiment will be described with reference to FIGS. 4 and 5.

FIG. 4 is a block diagram of the stage apparatus according to the other embodiment. A direct current is supplied from an AC power supply 22 to an inverter 20 via a rectifying circuit 23. A smoothing capacitor 24 is connected between a high-voltage-side power supply line and a low-voltage-side power supply line of the inverter 20. The inverter 20 includes a high-pressure-side switching element Q_{UH} and a low-pressure-side switching element Q_{UL} for a U phase, a high-pressure-side switching element Q_{VH} and a low-pressure-side switching element Q_{VL} for a V phase, and a high-pressure-side switching element Q_{WH} and a low-pressure-side switching element Q_{WL} for a W phase. For example, an insulated gate bipolar transistor is used for each of the switching elements. A freewheeling diode is connected to each of the switching elements.

Three-phase alternating current is output from a current path 50U for a U phase, a current path 50V for a V phase, and a current path 50W for a W phase of the inverter 20, and thus a motor 21 (actuator) is driven. For example, a linear motor is used as the motor 21. The movable stage 25 is driven by the motor 21.

Current measurement circuits 10U, 10V, and 10W are inserted in the current path 50U for a U phase, the current path 50V for a V phase, and the current path 50W for a W phase, respectively. As the current measurement circuits 10U, 10V, and 10W, the current measurement circuit 10 (FIG. 1) according to the one embodiment is used. Each of the current path 50U for a U phase, the current path 50V for a V phase, and the current path 50W for a W phase corresponds to the current path 50 (FIG. 1) in which the current measurement circuit 10 according to the one embodiment is inserted. The current measurement circuits 10U, 10V, and 10W measure instantaneous values of the alternating currents flowing through the current path 50U for a U phase, the current path 50V for a V phase, and the current path 50W for a W phase, respectively, at constant time intervals.

The current measurement values output from the current measurement circuits 10U, 10V, and 10W are input to a driver 30. The driver 30 controls the switching elements Q_{UH}, Q_{UL}, Q_{VH}, Q_{VL}, Q_{WH}, and Q_{WL} based on a command from a host controller 31 and the input current measurement value. For example, the command from the host controller 31 includes current target values for the U phase, the V phase, and the W phase.

Next, a procedure of controlling the motor 21 will be described with reference to FIG. 5. FIG. 5 is a flowchart showing the procedure of controlling the motor 21.

First, the current measurement circuits 10U, 10V, and 10W measure the currents flowing through the current path 50U for a U phase, the current path 50V for a V phase, and the current path 50W for a W phase, respectively, using the current sensor 11H for a large current (FIG. 1) and the current sensor 11L for a small current (FIG. 1) (step S1).

The selection circuit 15 (FIG. 1) selects one of the sensor outputs of the current sensor 11H for a large current and the current sensor 11L for a small current, based on the sensor outputs of the current sensor 11H for a large current and the current sensor 11L for a small current, and outputs the selected sensor output as the current measurement value (step S2). The current measurement value is input to the driver 30.

For example, when the amplitude of the current is within the linear characteristic range R_{L} of the current sensor 11L for a small current, the sensor output of the current sensor 11L for a small current is selected at all times within one period. When the amplitude of the current exceeds the linear characteristic range R_{L} of the current sensor 11L for a small current, the current sensor to be selected is switched between the current sensor 11L for a small current and the current sensor 11H for a large current within one period.

The driver 30 controls the inverter 20 based on the sensor output (current measurement value) selected in each of the current measurement circuits 10U, 10V, and 10W. The operation of the motor 21 is controlled by controlling the inverter 20 (step S3). Steps S1, S2, and S3 are repeatedly executed until the operation of the movable stage 25 ends (step S4).

Next, an excellent effect of the other embodiment will be described.

In the other embodiment, the current measurement circuit 10 (FIG. 1) according to the one embodiment is used as the current measurement circuits 10U, 10V, and 10W, and thus the currents flowing through the current paths 50U, 50V, and 50W are not affected even when the switching is performed between the current sensor 11L for a small current and the current sensor 11H for a large current. Therefore, the influence of noise caused by the switching can be eliminated, and thus the motor 21 can be stably controlled. For example, the malfunction of the movable stage 25 caused by noise is less likely to occur.

When the movable stage 25 is driven, it is necessary to flow a large current for the operation at a high speed. In addition, in order to improve the positioning accuracy when the movable stage 25 is stopped, high accuracy is required for the current measurement during driving with a small current.

In order to measure a large current during a high-speed operation, when only the current sensor 11H for a large current is used, as shown in FIG. 2, a large measurement error Err_{H} is generated in the measurement value when a small current flows. Due to this measurement error, it is difficult to improve the positioning accuracy of the movable stage 25 when the movable stage 25 is stopped. In the other embodiment, since the current sensor 11L for a small current (FIG. 1) is used when a small current is measured, as shown in FIG. 2, the measurement error Err_{L} is reduced. Therefore, it is possible to improve the positioning accuracy when the movable stage 25 is stopped.

Further, as shown in FIG. 3, the quantization error when a small current flows is reduced, and thus it is possible to more accurately perform the positioning.

The above-described embodiments are merely illustrative, and it goes without saying that portions of the configurations shown in the different embodiments can be partially substituted for or combined with one another. Similar operational effects produced by similar configurations across the plurality of embodiments will not be repeatedly described for each embodiment.

It should be understood that the invention is not limited to the above-described embodiment, but may be modified into various forms on the basis of the spirit of the invention. Additionally, the modifications are included in the scope of the invention.

What is claimed is:

1. A current measurement circuit comprising:
a plurality of current sensors that are inserted in a current path, that each have a different relationship between a current flowing through the current path and a sensor output, and that are connected in series with each other; and
a selection circuit that selects, based on a plurality of sensor outputs from the plurality of current sensors, one sensor output from among the plurality of sensor outputs and that outputs the selected sensor output as a current measurement value.

2. The current measurement circuit according to claim 1, wherein the plurality of current sensors each include a Hall element.

3. The current measurement circuit according to claim 1,
wherein the plurality of current sensors include a current sensor for a large current and a current sensor for a small current, and the relationship between the current flowing through the current path and the sensor output is different between the current sensor for a large current and the current sensor for a small current.

4. The current measurement circuit according to claim 3,
wherein a current transformer designed so that magnetic saturation does not occur when a maximum current flows is used as a current measurement element of the current sensor for a small current, and a shunt resistor is used as a current measurement element of the current sensor for a large current.

5. The current measurement circuit according to claim 2,
wherein the plurality of current sensors each include an AD converter that converts an analog signal output from the Hall element into a digital signal, and a resolution of the AD converter is different between the plurality of current sensors.

6. The current measurement circuit according to claim 3,
wherein the selection circuit provisionally determines a current value of the current flowing through the current path based on a sensor output of the current sensor for a large current, and selects a sensor output of the current sensor for a small current when the provisionally determined current value is within a linear characteristic range of a current measurement element of the current sensor for a small current.

7. The current measurement circuit according to claim 1, further comprising:
an inverter,
wherein an alternating current output from the inverter flows through the current path.

8. A stage apparatus comprising:
the current measurement circuit according to claim 7;
a movable stage;
an actuator driven by the inverter to move the movable stage; and
a driver that controls the inverter based on an output from the current measurement circuit.

9. A control method comprising:
measuring a current flowing through a current path using a plurality of current sensors that are inserted in series in the current path and that each have a different relationship between the current flowing through the current path and a sensor output; and
selecting, based on a plurality of sensor outputs of the plurality of current sensors, one sensor output from among the plurality of current sensors and controlling an actuator based on the selected sensor.
